(19) United States
(12) Patent Application Publication
(10) Pub. No.: US 2014/0144200 A1
(43) Pub. Date: May 29, 2014

(54) HOT METAL SHEET FORMING OR STAMPING TOOLS WITH CR-SI-N COATINGS

(71) Applicants: Arnd Muller, Malans (CH); Mathias Lukas Sobiech, Wasserburg (DE); Christian Maringer, St. Magarethen bei Knitterfeld (AT)

(72) Inventors: Arnd Muller, Malans (CH); Mathias Lukas Sobiech, Wasserburg (DE); Christian Maringer, St. Magarethen bei Knitterfeld (AT)

(73) Assignee: OERLIKON TRADING AG, TRUBBACH, Trubbach (CH)

(21) Appl. No.: 13/983,389

(22) PCT Filed: Jan. 28, 2012
(86) PCT No.: PCT/EP2012/000387

§ 371 Date: Oct. 15, 2013

(30) Foreign Application Priority Data
Feb. 4, 2011 (DE) 10 2011 010 401.1

(51) Int. Cl. B21D 37/01; C23C 14/06

(52) U.S. Cl. CPC B21D 37/01; C23C 14/0641
USPC 72/364; 428/446; 428/450

(57) ABSTRACT

The present invention discloses a CrSiN coated hot forming tool having enhanced wear resistance, oxidation resistance and adhesion wear resistance and thereby exhibiting a longer lifetime and better performance. The CrSiN coating is especially good to improve performance by hot metal sheet forming processes where the workpiece is an AlSi-coated metal sheet and/or a metal sheet with strength of 1,500 MPa or more.

The use of hot sheet metal forming processes for manufacturing new components, especially automobile components, has been increased considerably in the recent years. It has made necessary to bring into focus the difficulties that occurred by such processes. The present invention relates to the use of a Cr—Si—N coating system that enables life time and performance improvement of hot forming tools. A very good control of the friction level during this kind of operations is also attained thereby.

### STATE OF THE ART

In recent years high-strength steel sheets are used more and more for manufacturing automobile components in order to reduce the weight of automobiles and thus to reduce environmental problems and to improve collision safety at the same time. Many car components and structural members can be made significantly lighter by reducing the thickness of the high-strength steel sheets used for their manufacture. In Europe for example a hot metal sheet forming method called die quenching, hot forming, hot stamping or hot pressing is employed for fabricating automobile structural members having a strength of around 1,500 MPa. By this method, the strength of a steel sheet is increased through quenching after heating it to a temperature in the austenite temperature range, say, around 900° C. Heated steel sheet is extracted from a heating furnace, transferred to a pressing machine, formed into a prescribed shape using hot metal sheet forming tools maintained at room temperature, and thus quenched. At the forming work, the press machine is retained at the lower dead point until the entire steel sheet is quenched sufficiently (Senuma, T.: ISIJ Int. 41, 520 (2001)).

Generally speaking, as the strength of a steel sheet increases, its formability deteriorates, and to overcome this problem, various types of high-strength steel sheet products have been developed. For example, high-strength steel sheet with controlled microstructures or with Zn- or Al—Zn- or AlSi-coatings have been developed. In spite of these efforts, however, press forming complicated shapes is difficult when the strength of a steel sheet is as high as approximately 1,500 MPa (Senuma, T.: ISIJ Int. 41, 520 (2001)).

In Europe an aluminized steel sheet product called USIBOR 1500 (AlSi-coated) has been developed for this application. It has excellent hot-pressing properties and corrosion resistance qualities.

However, in spite of the very promising properties of metal coated steel sheets, they need much lubrication during forming operations due to the strong tendency of soft metal coating to adhere to the tool surface. After several successive forming cycles the adhered material may result in scratches and eventually cracks on the formed product. This problem is often called galling.

Furthermore the required lubrication may deteriorate the workshop environment and unhealthy degreasing agents are needed to remove the lubricant from the formed parts.

One concept to improve the current performance by hot metal sheet forming processes using coated metal sheets is to apply a low friction/high wear resistant PVD coating on the hot metal sheet forming tool. In the literature (Clarysse, F. and et al.: Wear 264 (2008) 400-404), basically two different types of PVD coatings are known: nitrides based coatings (e.g. CrN and TiAlN) and solid lubricants such as carbon or MoS₂ based layers (e.g. diamond-like carbon (DLC) and metal-MoS₂ composites).

Furthermore Francis Clarysse and et al. (Clarysse, F. and et al.: Wear 264 (2008) 400-404) investigated the behavior of different coating systems in tests especially designed in order to test the response of the coatings to galling. They observed that carbon-based composite layers (DLC-type and WC/C) perform outstanding as regards galling resistance. They recommend consequently to use this type of tool coatings instead of the typical hard coatings such as CrN, TiN, CrN/TiCrN.

Other known concept to improve the performance of hot metal sheet forming tools and thereby the surface quality of the thus manufactured components is the nitriding and the carbonitriding of the hot metal sheet forming tools, as well as to execute other kind of surface treatments on the hot metal sheet forming tools such as plasma treatments, micro-structuring, etc.

However the better hot metal sheet forming tool performance obtained using the above mentioned concepts do not improve sufficiently the process quality by hot sheet metal forming processes of coated high-strengh metal sheets. Especially using AlSi-coated high-strength steel sheets like USIBOR 1500 the galling phenomenon could not be satisfactorily reduced and continues being a problem.

### OBJECTIVE OF THE INVENTION

It is an objective of the present invention, to provide a hot metal sheet forming tool with a coating that improves satisfactorily die lifetime and performance of the tool. The coating should provide enough abrasive wear resistance, enough adhesive wear resistance and enough temperature stability. Principally, the coating should improve the protection against galling observed in AISi-coated steel sheets after hot metal sheet forming operations in comparison to the coating that are currently used.

### DESCRIPTION OF THE INVENTION

According to the present invention, hot forming tools are coated with CrSiN coatings. The inventors observed that CrSiN coatings improve considerably service lifetime and performance of hot metal sheet forming tools used by hot sheet metal forming processes.

CrSiN coatings are up to now known to be used as protection coating for dry machining tools (JP2005186184), where the operational demands and stress collective are completely different as the corresponding for hot metal sheet forming tools, where one of the big problems is for example the galling phenomenon that occurs when AISi-coated steel sheets are used as workpiece as was mentioned before.

The CrSiN coatings applied according to the invention exhibited very good abrasive wear, excellent temperature stability and an outstanding good reduction of AlSi-adhesion on the surface of the hot metal sheet forming tools and thus a very good solution to the galling problem that is normally observed in the surface of components manufactured from AISi-coated steel sheets by means of hot metal sheet forming operations. Preferably a coating thickness of between 4 μm and 8 μm of CrSiN is applied onto the substrate

The Cr—Si—N coatings were deposited according to the invention on hot metal sheet forming tools by means of physical vapour deposition (PVD) methods, particularly by means of reactive arc ion plating. Alloyed Cr:Si targets with different Cr and Si contents were used as material source for the deposition of the CrSiN coatings. The targets were activated in a nitrogen atmosphere producing the CrSiN coatings on the tool surface.

For coating of substrates (test samples and hot metal sheet forming tools or stamping tools) an Innova coating machine of the company Balzers was used. The hot metal sheet forming tools or stamping tools made of nitride steels and non-nitrided steels as well as the further test samples of different metal sorts were heated, etched and coated in the vacuum chamber of the coating machine by means of arc ion plating PVD process. During deposition the substrates were continuous rotated. In the coating step nitrogen was introduced in the vacuum chamber maintaining a pressure of ˜2×10⁻² mbar, six alloyed Cr:Si target with composition 95:5 at % were activated and a DC bias voltage of 40 V was applied.

It should be mentioned that the arc evaporation process leads to so called droplets in the CrSiN layer. These droplets are particles with metallic components which did not fully react with the reactive gas, which is for example nitrogen in the present case. The inventors found that hot sheet forming tools coated with CrSiN by arc evaporation are preferable. This might potentially be attributed to the presence of a limited, however existent number of droplets in the coating.

The CrSiN-coated hot stamping tools were tested by hot sheet metal forming of Usibor 1500 P® (Arcelor), which consists in fine-grain boron steel with Al—Si-based coating that is ca. 30 μm thick.

The anti-adhesion properties of these CrSiN coatings by hot sheet metal forming of Usibor 1500 P® were clearly better than the observed by identical tools used in identical forming processes but coated with different coating systems such as TiAlN, CrN, AlCrN, and AlCrSiN.

Additional wettability and lattice parameter of the CrSiN coatings were also measured.

The element composition of the CrSiN coatings deposited on hot forming tools according to the invention exhibited the following composition in atomic percentage taking into account as well the metallic elements as the non-metallic elements contained in the coating:

CrₓSi_{y}N_{z},
where x: 40-69%, y: 1-20% and z: 30-40%

The structure of the in such a way deposited CrSiN coatings was investigated by X-ray diffraction (XRD), scanning electron microscopy (SEM) and transmission electron microscopy (TEM) examinations. The formation of a crystalline structure was confirmed for all deposited coatings. All deposited coatings showed the preferred face centred cubic lattice. In the XRD patterns of the deposited CrSiN coatings peaks corresponding to preferential orientations of (111) and (200) lattice planes were observed. It was also observed that the peaks shifted by varying of Si-concentration in coating due to modifications of the chemical composition, the grain size and the residual stress. Coatings according to a preferred embodiment according to the present invention show peaks corresponding to preferential orientations of (111) and (222) lattice planes which are shifted as compared to the peaks of corresponding planes of pure CrN coatings. The degree of such shift gives an indication of the amount of the Si incorporated into the coating.

An important dependence between the Si content in the CrSiN coatings and their lattice parameter, wettability properties, and anti-adhesive behaviour against AlSi-coated metal sheets was observed.

The values of Si content in the CrSiN coatings for the following preferred embodiments of the invention are to be considered as calculated taking only the metallic elements in the coating into account. That means taking only Cr and Si into account.

A preferred embodiment according to the invention is obtained using CrSiN coatings having Si content in the coating of >0 up to 15 at %.

A further preferred embodiment according to the invention is obtained using CrSiN coatings having Si content in the coating of 2-10 at %.

A most preferred embodiment according to the invention is obtained using CrSiN coatings having Si content in the coating of 3-8 at %.

According to the present invention a CrSiN coating is used as coating for a hot forming tool. The present invention discloses a tool for hot metal sheet forming having a CrSiN hard coating. Said CrSiN hard coating specially having a Si content in a film in range of >0 up to 15 at %, preferably 2-10 at %, more preferably 3-8 at % taking into account only the metallic elements for calculating the mentioned Si content in atomic percentage.

A further preferred embodiment according to the present invention is obtained using hot thermal conductivity steel (HTCS) or nitrided steel or carbonitrided steel as tool substrate or any other previous surface treated steel tool as tool substrate.

The present invention discloses a tool for hot metal sheet forming coated with CrSiN according to the invention, wherein said CrSiN hard coating is formed by an arc ion plating method.

The present invention discloses a hot sheet metal forming process where a tool coated according to the invention is used in order to improve the service life time of the hot forming tool and overall performance and thereby also to improve the quality of the by means of this process manufactured metal sheet.

The present invention considers specially a hot sheet metal forming process where a tool coated according to the invention is used to form AlSi coated metal sheets and/or to form metal sheets, whose material possesses strength of around 1,500 MPa or more.

What is claimed is:

1. Hot metal sheet forming tool having a CrSiN hard coating.

2. A tool according to claim 1, wherein said CrSiN hard coating is characterized by a Si content in a film being >0 up to 15 at %, preferably 2-10 at %, more preferably 3-8 at %.

3. A tool according to claim 1, wherein the tools substrate is a hot thermal conductivity steel or nitrided steel or a carbonitrided steel or any other previous surface treated steel.

4. A tool according to claim 1, wherein the tools substrate is a non-nitrided steel.

5. A tool according to claim 1, wherein said CrSiN hard coating is formed by arc ion plating.

6. Hot sheet metal forming process for manipulating a workpiece, where a tool according to claim 1 is used.

7. A hot sheet metal forming process according to claim 6, wherein the workpiece is an AlSi-coated metal sheet.

8. A hot sheet metal forming process according to claim 6 wherein the workpiece is a metal sheet having strength of around 1,500 MPa or more.

9. Use of a CrSiN coating as a coating on a hot metal sheet forming tool.
